(19) United States
(12) Patent Application Publication
(10) Pub. No.: US 2018/0113175 A1
(43) Pub. Date: Apr. 26, 2018

(54) DETECTION EQUIPMENT FOR BACKLIGHT MODULE

(71) Applicants: BOE Technology Group Co., Ltd., Beijing (CN); Beijing BOE Chatani Electronics Co., Ltd., Beijing (CN)

(72) Inventor: Zirui Niu, Beijing (CN)

(21) Appl. No.: 15/501,194

(22) PCT Filed: Jun. 29, 2016
(86) PCT No.: PCT/CN2016/087603

§ 371 Date: Feb. 2, 2017

(30) Foreign Application Priority Data
Oct. 19, 2015 (CN) 201510676235.7

(51) Int. Cl. G01R 31/44; G01R 1/04

(52) U.S. Cl. CPC G01R 31/44; G01R 1/0408

(57) ABSTRACT

A detection equipment is provided in an embodiment of the present disclosure, including: a platform on which an item to be detected is placed; a rotary device provided underneath the platform, wherein the rotary device is configured to rotate the platform according to an input angle.

### CROSS-REFERENCE TO RELATED APPLICATION

This application claims the benefit of Chinese Patent Application No. 201510676235.7 filed on Oct. 19, 2015 in the State Intellectual Property Office of China, the whole disclosure of which is incorporated herein by reference.

### FIELD OF THE INVENTION

Embodiments of the present disclosure relate to a detection equipment, especially to a detection equipment for a backlight module.

### BACKGROUND OF THE INVENTION

It is necessary to use a detection equipment to perform a backlight test on a display panel or a backlight module after they are manufactured.

When a detection equipment in the prior art is used to perform a lighting test on a display panel, the display panel is usually placed onto a platform of the detection equipment, then a signal is loaded to the display panel, thereby testing the display quality of the display panel.

However, the detection equipment in the prior art cannot rotate automatically. For example, if it is needed to rotate the display panel about a vertical axis by 45°, it can only be achieved through manual rotation. In this way, the angle of rotation of the display panel is usually determined in a rough manner such as by visual observation, and the accuracy of the test to the display panel is degraded due to inaccuracy of the rotation angle. As a result, it will cause an error in the final evaluation of the display panel.

### SUMMARY OF THE INVENTION

The present disclosure has been made to overcome or alleviate at least one aspect of the above described disadvantages.

According to an aspect of the present invention, there is provided a detection equipment.

According to an exemplary embodiment, the detection equipment may comprise: a platform on which an item to be detected is placed; a rotary device provided underneath the platform. The rotary device is configured to rotate the platform according to an input angle.

According to another embodiment, the detection equipment may further comprise an angle identifying device configured to identify a rotation angle of the rotary device or a rotation angle of the platform.

According to another embodiment, the detection equipment may further comprise a plurality of height adjustment devices disposed underneath the platform, wherein each of the height adjustment devices is configured to be independently adjustable so as to adjust the height or tilt angle of the platform.

According to another embodiment, the detection equipment may further comprise a user interface configured to receive an instruction input by a user.

According to another embodiment, the detection equipment may further comprise a fixing device for fixing the item to be detected. In case that the item to be detected comprises a backlight module, the fixing device is configured to at least fix an outlet terminal of the backlight module.

According to another embodiment, the fixing device is made of an elastic material.

According to another embodiment, the detection equipment may further comprise a base on which the rotary device is disposed.

According to another embodiment, the base is provided with an endless track, and the plurality of height adjusting devices are configured to be movable along the endless track. According to another embodiment, the rotary device comprises a rotary shaft by which the rotary device drives the platform to rotate.

According to another embodiment, the rotary device is a pneumatic rotary device or a hydraulic rotary device.

With a rotary device being provided, it can accurately rotate the platform by a certain angle, thereby improving the accuracy of the test to the backlight module or the display panel.

### BRIEF DESCRIPTION OF THE DRAWINGS

The above and other features of the present invention will become more apparent by describing in detail exemplary embodiments thereof with reference to the accompanying drawings, in which:

FIG. 1 is a schematic diagram of a detection equipment according to an embodiment of the present disclosure;

FIG. 2 is another schematic diagram of the detection equipment according to an embodiment of the present disclosure;

FIG. 3 is another schematic diagram of the detection equipment according to an embodiment of the present disclosure, in which the detection equipment of FIG. 1 is shown upside down; and

FIG. 4 is a partial schematic diagram of the detection equipment according to an embodiment of the present disclosure in which a cross-section of a central portion of the detection equipment is shown.

### DETAILED DESCRIPTION OF PREFERRED EMBODIMENTS OF THE INVENTION

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

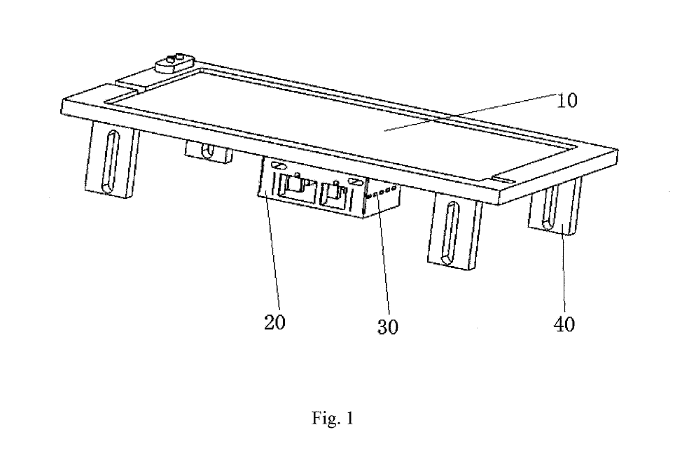

FIG. 1 is a schematic diagram of a detection equipment according to an embodiment of the present disclosure for a backlight module. As shown in the Figure, the detection equipment comprises: a platform 10 on which a backlight module can be placed; a rotary device 20 provided underneath the platform 10. The rotary device 20 is configured to rotate the platform 10 according to an input angle.

In an embodiment of the present disclosure, the detection equipment may further comprise an angle identifying device 30 configured to identify a rotation angle of the rotary device 20 or a rotation angle of the platform 10.

The detection equipment may further comprise a base on which the rotary device 20 is disposed. In an exemplary embodiment, the rotary device may be fixed onto the base, and the rotary device may drive the platform to rotate with a rotary component. In another exemplary embodiment, the rotary device may rotate as a whole and is rotatablely mounted on the base. The platform is driven to rotate by the rotary device's own rotation.

It is possible to determine if the platform 10 has been rotated to a desired angle or and input angle by identifying the rotation angle of the rotary device 20 or the rotation angle of the platform 10 by the angle identifying device 30. For example, the rotation angle of the rotary device 20 or the rotation angle of the platform 10 identified by the angle identifying device 30 is compared with the input angle, and the rotation direction of the rotary device 20 is adjusted in accordance with the comparison result. If it is determined that the rotation angle of the rotary device 20 or the rotation angle of the platform 10 is equal to the input angle, the rotary device 20 is controlled to stop the rotation of the platform. For example, an angle identifier commonly used by those skilled in the art may be used as the angle identifying device 30 described above, although other suitable angle identifying devices (e.g., angle sensors, etc.) may be used as an angle identifying device 30 by a person skilled in the art.

As shown in FIG. 1, according to an embodiment of the present disclosure, the detection equipment may further comprise a plurality of height adjustment devices 40 disposed underneath the platform 10. In an exemplary embodiment, each of the height adjustment devices is configured to be independently adjustable so as to adjust the height or tilt angle of the platform 10. In a further embodiment, the height adjustment devices comprise height adjustable columns. The columns may be connected between the platform and the base. In an exemplary embodiment, the columns may include telescopic hydraulic means. In an exemplary embodiment, the base is provided with an endless track, and the plurality of height adjusting devices are configured to be movable along the endless track. The adjustable columns fixedly connected to the platform are movable along the endless track when the rotary device drives the platform to rotate. In an alternative embodiment, it is also possible that an endless track is provided underneath the platform and the plurality of height adjustment devices are configured to be fixedly mounted on the base and mounted to the endless track underneath the platform, such that the platform may rotate relative to the columns through the track.

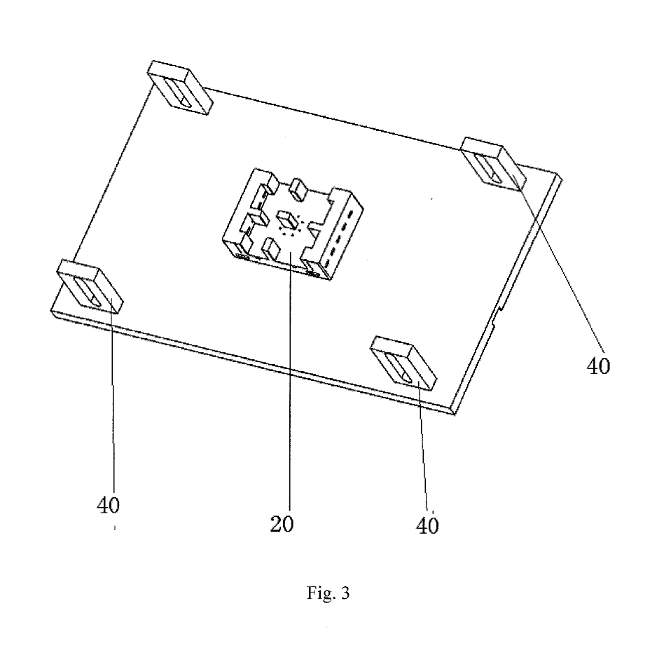

Although there are four columns shown in the figure (FIG. 3), the present disclosure is not limited thereto. In other embodiments, the platform may comprise only three columns. By independently adjusting the height of each column, it also possible to make the platform have different inclination angles in different directions. In the case that there are four columns, two adjacent columns may be adjusted simultaneously to change the inclination angle of the platform. Of course, if the heights of all the columns are adjusted simultaneously, the platform may be raised or lowered as a whole.

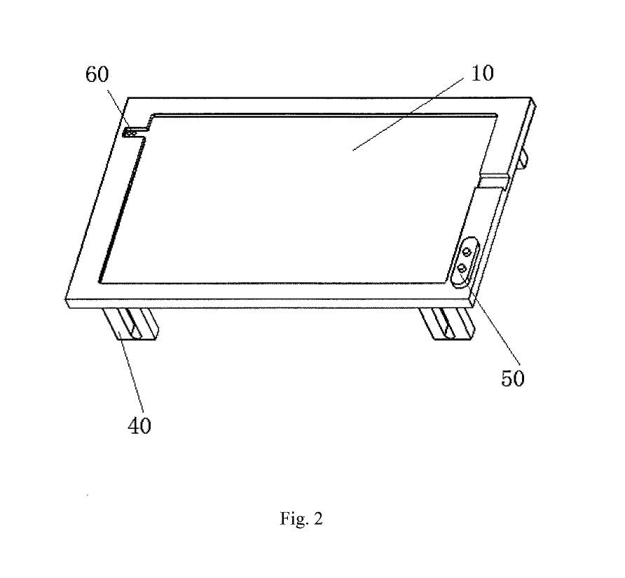

FIG. 2 is another schematic diagram of the detection equipment according to an embodiment of the present disclosure. As shown in the Figure, the detection equipment may further comprise a user interface configured to receive an instruction input by a user. In an exemplary embodiment, the user interface may include a knob 50 disposed on the platform (e.g., disposed close to an edge of the platform), through which the operator may input a command instructing the rotation angle of the platform. For example, a scale for indicating the angle can be provided around the knob. When the knob is rotated to a certain scale, it is indicated that the user wants the platform to be rotated to the angle.

In other embodiments, the user interface may further comprise other command receiving means or components for receiving commands about the inclination angle or height of the platform.

FIG. 3 is another schematic diagram, in which the detection equipment of FIG. 1 is shown upside down. In FIG. 3, a positional relation of the different components of the detection equipment is shown in another direction. The rotary device 20 is provided underneath the platform 10, and according to an embodiment of the present disclosure, the rotary device is arranged at the center of the platform. Of course, those skilled in the art may also arrange the rotary device at other positions according to the type and structure of the rotary device, and such positions do not constitute a limitation to the present disclosure.

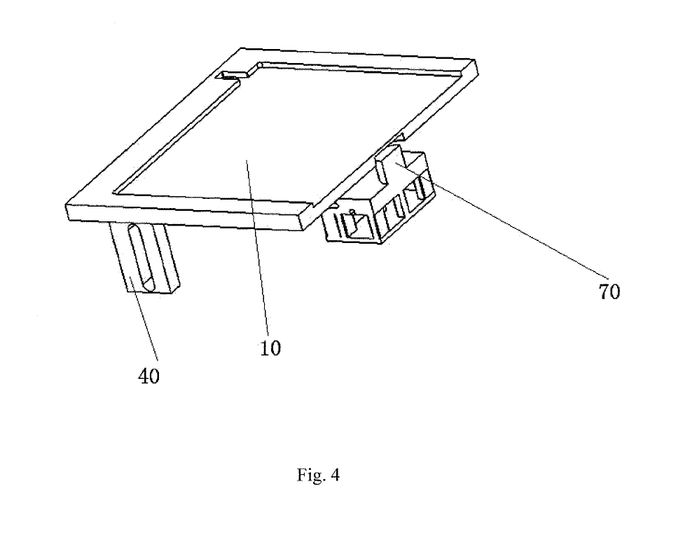

FIG. 4 is a partial schematic diagram of the detection equipment according to an embodiment of the present disclosure in which a cross-section of a central portion of the detection equipment is shown to better illustrate an interrelationship of the respective parts of the detection equipment. In an embodiment of the present disclosure, as shown in FIG. 4, the rotary device 20 comprises a rotary shaft 70 through which the rotary device 20 is connected to the platform of the detection equipment and drives the platform 10 to rotate. Here, the rotary device 20 may be a pneumatic rotary device 20 or a hydraulic rotary device 20. The examples shown in the figures of the embodiments of the present disclosure use a pneumatic rotary device, which can be chosen by those skilled in the art, as desired. In addition, the above described pneumatic rotary device and hydraulic rotary device can be known pneumatic rotary device and hydraulic rotary device in the prior art.

Further referring to FIG. 2, the detection equipment according to another embodiment may further comprise a fixing device 60 made of an elastic material (such as a rubber), which is configured to press an outlet terminal of the backlight module to prevent a damage thereto. An electrical interface may be provided underneath the platform for powering the detection equipment. In an embodiment of the present disclosure, the platform may be made of bakelite plastic, although other materials may be used by those skilled in the art to manufacture the platform.

Hereinafter, the operation of the detection equipment of the embodiment of the present disclosure will be further described, in which the difference from the prior art will be described in detail, and the same operation will be omitted. To check a backlight module at a certain angle and a certain height, the operator needs to input a preset angle. According to an embodiment of the present disclosure, the operator may input a rotation angle with the knob 50, then the rotary device rotates the platform. The platform can accurately rotate by an angle with the rotary device. Compared to a manual rotation mode, it remarkably improves the accuracy of the test to the display panel.

According to an embodiment of the present disclosure, the rotation angle of the rotating device can be identified by an angle identifying device. Basing on the result of identification, it is determined whether the preset angle is reached. If the preset angle is reached, the rotating device stops the rotation, and if the rotation angle has not yet been reached, the rotating device continues to rotate. By providing the angle identifying device, it may further improve the accuracy of the rotation angle, thereby improving the accuracy of the test to the display panel.

An adjustment to the height and the inclination angle of the platform may be performed after the adjustment of the rotation angle of the platform of the detection equipment. In an embodiment of the present disclosure, the plurality of height adjustment devices are provided underneath the platform. The height adjustment devices are arranged to be independently adjustable, for example by telescoping of the columns, to adjust the height or inclination angle of the platform. With the above described detection equipment, the height and the inclination angle of the display panel can be accurately adjusted.

After the above operations are finished, the backlight module is tested. The present application may include all or part of the above steps according to actual requirements, which does not constitute a limitation of the present disclosure. With the detection equipment provided by the embodiments of the present disclosure, the drawbacks of the prior art detection equipment are overcome and the accuracy of test to the display panel is improved.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

What is claimed is:

1. A detection equipment comprising:
a platform on which an item to be detected is placed;
a rotary device provided underneath the platform,
wherein the rotary device is configured to rotate the platform according to an input angle.

2. The detection equipment according to claim 1, further comprising:
an angle identifying device configured to identify a rotation angle of the rotary device or a rotation angle of the platform.

3. The detection equipment according to claim 1, further comprising:
a plurality of height adjustment devices disposed underneath the platform, wherein each of the height adjustment devices is configured to be independently adjustable so as to adjust the height or tilt angle of the platform.

4. The detection equipment according to claim 1, further comprising:
a user interface configured to receive an instruction input by a user.

5. The detection equipment according to claim 1, further comprising:
a fixing device for fixing the item to be detected,
wherein the item to be detected comprises a backlight module, and the fixing device is configured to at least fix an outlet terminal of the backlight module.

6. The detection equipment according to claim 5, wherein the fixing device is made of an elastic material.

7. The detection equipment according to claim 1, further comprising:
a base on which the rotary device is disposed.

8. The detection equipment according to claim 7,
Wherein the base is provided with an endless track, and the plurality of height adjusting devices are configured to be movable along the endless track.

9. The detection equipment according to claim 1, wherein the rotary device comprises a rotary shaft by which the rotary device drives the platform to rotate.

10. The detection equipment according to claim 7, wherein the rotary device is a pneumatic rotary device or a hydraulic rotary device.
